(19) United States
(12) Patent Application Publication
(10) Pub. No.: US 2025/0349917 A1
(43) Pub. Date: Nov. 13, 2025

(54) Method and device for preventing or reducing the risk of a short circuit caused by dendrites in a lithium -ion rechargeable battery

(71) Applicant: Ulrich Twelmeier, Pforzheim (DE)

(72) Inventor: Ulrich Twelmeier, Pforzheim (DE)

(21) Appl. No.: 18/572,181

(22) PCT Filed: Jun. 13, 2022
(86) PCT No.: PCT/EP2022/065966

§ 371 Date: Dec. 20, 2023

(30) Foreign Application Priority Data
Jun. 20, 2021 (DE) 10 2021 003 117.2

(51) Int. Cl. H01M 10/44; G01R 31/389; H01M 10/0525

(52) U.S. Cl. CPC H01M 10/441; G01R 31/389; H01M 10/0525; H01M 10/446; H01M 10/448; H01M 2200/00; H01M 2220/20

(57) ABSTRACT

A method for influencing the growth of lithium dendrites in a lithium-ion rechargeable battery having in a cell (1) a cathode (4) and opposite the latter an anode (3) consisting of lithium or having at least one surface containing lithium, an anhydrous electrolyte (5) being situated in an interspace between the cathode (4) and the anode (3) and a separator (6) permeable to lithium ions being arranged in said interspace. During an electrical charging process, longitudinal ultrasonic waves having a variable frequency are generated in the cell (1) or transmitted into the cell (1), the longitudinal direction of the ultrasonic waves in the electrolyte (5) extending transversely to the normals (16) to the anode (3) and the cathode (4), and the frequency of the ultrasonic waves being controlled such that it repeatedly passes through a frequency range.

The invention relates to a method having the features specified in the preamble of claim 1 and to a device having the features specified in the preamble of claim 18.

For a long time it has been known that, when rechargeable lithium-ion batteries, hereinafter lithium-ion accumulators, are repeatedly charged, lithium dendrites grow on their anodes consisting of metallic lithium. The dendrites can reach the cathode, which is placed opposite the anode and can then cause an electric short circuit, which may result in fire and even in an explosion of the accumulator. Thus it was necessary to look for alternatives for anodes made of metallic lithium and found as alternatives e.g. anodes which are made of graphite or of other layered materials, between the layers of which lithium ions can be stored when charging the accumulator, the storing being referred to as “intercalation” in English language technical literature. Irrespective of this, there is still a great interest in anodes made of metallic lithium, because they would enable particularly powerful accumulators. However, it is important for their acceptance if one could eliminate or reduce the danger induced by the lithium dendrites. There has therefore been no lack of attempts to counteract the formation of dendrites in lithium-ion accumulators.

EP 3 033 797 B1 names dendrites as “the most common failure mode for cells with Li metal anodes” and proposes providing a large number of pressure sensors along the anode, which are intended to record the extent of a change in the shape of the anode associated with the charging process. If the measured pressure exceeds a specified limit value, then—to be on the safe side—the accumulator is disconnected or partially discharged, which however does not solve the problem. Alternatively EP 3 033 797 B1 proposes, after the pressure exceeded a limit value, to change the spatial distribution of the charging current in such a way, that the change in shape of the anode caused by a previous charging process is partially reversed. However, it is not disclosed how this could be achieved and what effort would be associated with it.

U.S. Pat. No. 8,354,824 B2 even proposes to discharge the accumulator completely from time to time in order to reduce the roughness of the surface of the anode and to reform dendrites that have already formed. This proposal also does not really solve the problem of dendrite growth and is in particular not suitable for applications in accumulators for electrically or partially electrically driven automobiles.

U.S. Pat. No. 5,728,482 A proposes reducing the growth of dendrites on a lithium anode of an accumulator by generating in the area in front of the surface of the anode a magnetic field, the field lines of which run transversely to the electric field between the cathode and the anode of the accumulator. The magnetic field is to shield protrusions on the surface of the anode, on which—if not shielded—during the charging process the electric field between cathode and anode might concentrate, so that the unshielded protrusions could be starting points for lithium dendrites. However, this can be only partially successful, especially since even smallest projections can be starting points for dendrites, as can be obtained from the following reference:

The most recent insight into the origins of lithium dendrite formation can be found in the research article by Elizabeth Santos and Wolfgang Schlicker entitled “Die entscheidende Rolle von lokalen Ladungsfluktuationen beim Wachstum von Dendriten auf Lithium-Elektroden” (In English Translation: The Crucial Role of Local Charge Fluctuations in Dendrite Growth on Lithium Electrodes), published in the Journal of Angew. Chem., 2021, 135, 5940-5945. According to this, model calculations show that peaks of small bumps on the surface of the anode, the peaks consisting of just a few atoms, can attract the lithium ions present in the electrolyte of the accumulator during the charging process and allow them to grow into dendrites. In the research article, the authors conclude that their model gives a reason for the formation of dendrites, but no recipe for avoiding their formation.

It is an object of the invention to show a practicable and promising way how in a lithium-ion accumulator comprising a liquid anhydrous electrolyte and an anode whose surface facing an opposite cathode consists predominantly or entirely of lithium, it can be avoided or delayed the occurrence of an electrical short circuit caused in the accumulator by lithium dendrites, which might form during charging the accumulator.

Said object is achieved by a method having the features specified in claim 1. Advantageous further developments of the invention are the subject matter of the dependent claims.

In order to avoid or reduce the risk of short circuits caused by lithium dendrites in a lithium-ion accumulator, which in a cell comprises a cathode and opposite the cathode an anode consisting of lithium or at least having a lithium containing surface, and which comprises in an interspace between the cathode and the anode a liquid anhydrous electrolyte and a separator permeable to lithium ions, the invention teaches a method in which during a charging process longitudinal ultrasonic waves, of which the longitudinal direction in the electrolyte is running transverse to the normals to the anode and to the cathode, are generated in the cell or transmitted into the cell with a variable frequency, which is so controlled that it repeatedly runs through a range of frequencies. Accordingly, the longitudinal ultrasonic waves run transversely to the direction in which the lithium ions migrate from the cathode to the anode while the accumulator is charged.

For convenience, longitudinal ultrasonic waves having an orientation in accordance to the invention, are hereinafter referred to as longitudinal ultrasonic waves.

The claims are to be understood in such a way that the accumulator may have one cell or a plurality of cells which—in particular for use in electromobility—may be combined into one or a plurality of packages. The cells may be electrically connected in series to achieve a higher output voltage. The cells may be electrically connected in parallel to allow a higher output current and hence a higher output power. Groups of cells, in which the cells are electrically connected in series, may be electrically connected in parallel. Groups of cells, in which the cells are electrically connected in parallel, may be electrically connected in series. In all of these cases, the ultrasound can either be generated in each individual cell or generated on an outer wall of the respective cell or in a recess in an outer wall of the respective cell and transmitted from there into the cell.

The generation of ultrasonic waves “during a charging process” is to be understood in such away that the charging process can be the initial charging as well as a recharging of the accumulator.

The indication that the longitudinal direction of the ultrasonic waves is “transverse” to the normals to the anode and to the cathode does not mean that the longitudinal direction of the ultrasonic waves has to intersect the normals at a right angle. It is sufficient that the longitudinal direction of the ultrasonic waves crosses the normals at any angle, with a right angle or an approximately right angle being preferred.

The method according to the invention may be carried out during each charging process or during selected charging processes, for example during every second or third charging process, or only when the charging process takes place at a stationary charging station. Preferably, the method according to the invention is carried out during each charging process that takes place at a stationary charging station. In case of vehicles that are hybrid driven, i.e. that they have both an electric motor drive and an internal combustion engine, in view of frequent and irregular changes between charging and discharging processes it might be more expedient, not to use the method according to the invention while driving, or not in each phase of a trip in which the internal combustion engine is working. Preferably, however, the method according to the invention is carried out in vehicles, that are equipped with a lithium-ion accumulator, also while driving, in order to avoid also while driving the occurrence of short circuits as far as possible. The decision to start charging may be made dependent on the state of charge of the accumulator falling below a predetermined threshold value. It is known to automatically monitor the state of charge of the accumulator while driving, so that the internal combustion engine and the charging process can be started automatically when the charge of the accumulator falls below the threshold value.

The method according to the invention may be carried out during the entire duration of the charging process or only during part of the duration of the charging process. If the method is carried out for all cells of an accumulator during the entire charging process, then the risk of an electrical short circuit caused by a lithium dendrite is lowest. If the method is not carried out during the entire duration of the charging process of a cell, then in the case of an accumulator composed of several cells or of many cells, it is possible to carry out the method on individual cells or groups of cells at different times, which might overlap, but do not have to overlap. This variant of the method according to the invention would have the advantage that the power requirement of the accumulator for generating the ultrasonic waves can be reduced.

The teaching of generating during a charging process longitudinal ultrasonic waves having an orientation according to the invention does not exclude the possibility, that longitudinal ultrasonic waves oriented according to the invention, in particular shock waves, may additionally be generated in the electrolyte or transmitted into the electrolyte also outside of a charging process. Lithium dendrites, which are not long enough to cause a short circuit, may be broken by longitudinal ultrasonic waves generated with variable frequency and also by ultrasonic shock waves. In doing so the risk of a short circuit arising from dendrites that have formed during charging the accumulator may be eliminated or reduced.

Ultrasonic shock waves, which also are referred to as ultrasonic impulse waves, are ultrasonic pulses that are characterized by a rapid increase in pressure and by a short pulse duration. They may be generated from time to time while no frequency sweep occurs. Preferably, they are generated toward the end of a charging process or after completion of a charging process, because then any dendrite that may have been formed during the charging process had for the longest time the opportunity to grow.

While charging the accumulator, the longitudinal ultrasonic waves generated according to the invention in the electrolyte worsen the conditions for the formation and growth of lithium dendrites. Lithium ions, which migrate to the anode while the accumulator is charged, should as far as possible be prevented from preferentially sticking to pointed projections on the anode. The method according to the invention counteracts the tendency of the lithium ions to preferentially precipitate on pointed projections of the anode by disrupting the migration of the lithium ions in a targeted manner. In the electrolyte the longitudinally oscillating ultrasonic waves can superimpose a sideways movement on the migration movement of the lithium ions from the cathode to the anode, which superimposition may cause a lithium ion to deflect from its path directed to a pointed protrusion on the anode, so that effectively the lithium ion will not precipitate “at rest” on the pointed protrusion, but instead will precipitate at a different location which is adjacent to the pointed protrusion on the anode, so that thereafter the protrusion will be less prominent than before. As a result, under the influence of the longitudinal ultrasonic waves the deposition of lithium ions on the anode is evened out, which makes it difficult for dendrites to form on the anode.

The longitudinal ultrasonic waves hit the side of any dendrite that may have formed in the electrolyte and can excite it to transversal vibrations (bending vibrations), which may break it, especially when a resonance occurs or when the dendrite is impacted by shock waves. Also on these grounds it is an advantage of the invention that the frequency of the ultrasound is controlled in such a way that it repeatedly runs through a frequency range. By repeatedly running through a sufficiently broad frequency range it is possible to ensure that useful resonances are run through, even without a more precise knowledge of the frequencies at which resonances might occur in the electrolyte and in any dendrites that eventually have been generated. As already mentioned, a sufficiently broad frequency range can be ensured by pretests. In addition, it is advantageous that frequency generators and ultrasonic transducers for large frequency ranges from 20 KHz to the megahertz range are commercially available.

The targeted disruptions of the migration of the lithium ions on their way from the cathode to the anode, which are desired when charging the accumulator, are particularly effective when they are amplified by the occurrence of resonances. The frequencies at which resonances can occur depend on a number of influencing factors, including the structure of the cell, the materials used, the temperature, the viscosity of the electrolyte, the strength of the charging current, the state of charge of the accumulator and the age of the accumulator. It is therefore a particular advantage of the invention that the frequency of the ultrasound is varied and repeatedly runs through a frequency range.

For this purpose, advantageously there is provided a frequency generator, which feeds one or a plurality of ultrasonic transducers generating the ultrasonic waves. At the frequency generator can be set the frequency range to be run through, the duration of a complete run through the selected frequency range, and the power with which the frequency generator feeds one or a plurality of ultrasonic transducers, wherein the power of the frequency generator may be selected depending on the frequency. Since a frequency range is run through repeatedly, it can be ensured that in any case one or more resonances can be used for the purposes of the invention, regardless of whether the exact position of the resonance frequencies is known, which—as noted above—may vary continuously. Preferably the frequency of the ultrasound is changed cyclically, so that resonance frequencies in the selected frequency range are run through again and again, thereby increasing the effectiveness of the method according to the invention.

The repeated running through a frequency range is also advantageous because shorter lithium dendrites are more likely to be influenced in the meaning of the invention by higher ultrasonic frequencies than longer lithium dendrites, which are more likely to be influenced within the meaning of the invention by lower ultrasonic frequencies. Accordingly, both longer dendrites and shorter dendrites have a chance of being damaged by exposure to longitudinal ultrasonic waves of variable frequency, e.g. being “decapitated”. The chance increases if additionally ultrasonic shock waves are generated from time to time.

Occurring resonances may have a retroactive effect on the ultrasonic transducers and further on a frequency generator feeding them. The frequency generator is preferably set up to detect such retroactions when the strength of the retroaction exceeds a threshold that depends on the design of the frequency generator. The frequency generator can so be programmed that each time it detects a retroaction caused by a resonance, it stops changing the frequency for a preset duration in order to increase the dwell time at the resonance and thus to increase the inhibitory effect of the longitudinal ultrasonic waves on the formation and growth of lithium dendrites. Of course, one has to be careful to limit from the first the intensity of the ultrasound in such a way that damage to the accumulator and its components is avoided, particularly in the event that resonances occur and shock waves are generated. Pretests can be used to determine which ultrasonic intensities a specific accumulator can tolerate without being damaged.

Influencing the migration of the lithium ions in such a way that they precipitate less frequently on pointed projections of the anode requires less energy than breaking dendrites that already have been formed. Accordingly, the power with which the ultrasonic transducers are fed is preferably adjustable.

The frequency range in which useful resonances occur can be determined experimentally in advance for each specific design of an accumulator. The frequency generator can be tuned or set up to a frequency range in which one or more than one experimentally determined resonance points are found. In doing so, low resonance frequencies are preferred when determining the frequency range which is to be run through repeatedly.

During discharging is the accumulator preferably not exposed to ultrasound in order to not disturb the discharging process, and also because no lithium ions are deposited on the anode during discharging, on the contrary: Lithium dendrites formed during charging of the accumulator may even partially regress again during discharging.

Preferably the longitudinal ultrasonic waves are generated in the electrolyte with a piezo-electric ultrasonic transducer. Piezo-electric ultrasonic transducers are already known e.g. for cleaning purposes, for use in measurement technology, for welding plastics and for diagnostic purposes. They are available in numerous designs that are adapted to the particular application. They can also be adapted for purposes of the invention. Piezo-electric ultrasonic transducers with a flat design are particularly suitable for this. Ultrasonic transducers in a flat design are available in different sizes and shapes, including rectangular formats whose dimensions can be adapted to the dimensions of the cells in lithium-ion accumulators.

In the present case, the ultrasonic transducer is mounted preferably at an outer wall of the cell delimiting the interspace between the cathode and the anode. Depending on the given spatial conditions, the ultrasonic transducer can be located close to the anode in order to counteract the formation of lithium dendrites already from the beginning. In addition, a further transducer can be located close to the cathode. As an alternative, it is possible to provide an ultrasonic transducer that extends at the outer wall across the position of the separator to near the position of the anode and to near the position of the cathode.

Arranging the ultrasonic transducer or transducers, resp., at the inside of the outer wall of the cell has the advantage that the ultrasonic transducer can emit the longitudinal ultrasonic waves directly into the electrolyte. Arranging the ultrasonic transducer at the outside of the outer wall of the cell has firstly the advantage, that its arrangement there is simpler, and has secondly the advantage that in an accumulator in which several cells are arranged next to one another it is possible to place an ultrasonic transducer between two cells and in this way to use it twice, namely by emitting ultrasound in opposite directions. In this way, a rear shielding of the piezo-electrically oscillating element, which is otherwise customary, is no longer necessary in the ultrasonic transducer.

Another advantageous possibility is an integration of the ultrasonic transducer into the outer wall of the cell or in a recess provided in the outer wall of the cell. By this type of attachment the ultrasonic transducer can emit the longitudinal ultrasonic waves directly into the electrolyte without disturbing the internal structure of the cell.

Piezo-electric ultrasonic transducers are compact and can easily be coupled to flat surfaces, which are found in accumulators or can be realized in accumulators. They are available in a wide frequency range from 20 kHz to the megahertz range, are easy to control and can obtain the electrical power for their operation from the accumulator itself.

The longitudinal ultrasonic waves do not only impede the beginning of the formation of lithium dendrites, but also their growth in the direction toward the cathode. The chance that a lithium dendrite will be broken by its interaction with the longitudinal ultrasonic waves increases with increasing length of the dendrite, with increasing power transmitted by the ultrasonic transducers and with decreasing frequency of the ultrasonic waves. If the frequency of the ultrasound remains constant, stationary waves could form within a cell of the accumulator, as a result of which the lithium could be deposited unevenly on the anode. The invention advantageously avoids this disadvantage in that the frequencies of the ultrasound are variable and repeatedly run through a frequency range.

If a lithium dendrite has formed on the anode despite the impact of ultrasonic waves, then there arises the question as to whether it can overcome the separator. Since the separator is permeable to lithium ions, a lithium ion coming from the cathode can pass through the separator and may be deposited behind the separator on the tip of a dendrite. However, the longitudinal ultrasonic waves in the adjacent electrolyte counteract the dendrite from growing into the separator by exciting the tip of the dendrite to vibrate. Firstly, there is a chance that the oscillating tip of the dendrite interacting with the separator will break off. Secondly, as explained using the example of the anode, the ultrasonic vibrations in the electrolyte will disrupt the deposition of further lithium ions on the tip of the dendrite, as a result of which its growth is impeded or inhibited as compared to the migration of lithium ions that is not disrupted by ultrasound. Even if the ultrasonic vibrations in the electrolyte would excite the separator to ultrasonic vibrations, the vibrations excited in the separator would neither nullify the effect of the vibrations in the electrolyte nor the effect of the vibrations of the tip of the dendrite on the growth of the dendrite, because they follow each other with different time delays and because longitudinal oscillations as well as transversal oscillations are possible in the separator. Rather, an excitation of ultrasonic vibrations in the separator can also make it more difficult for dendrites to grow into the separator.

Should nevertheless a lithium dendrite be able to grow into and through the separator and reach the cathode, then there is another chance, that the tip of the dendrite will be broken off by its interaction with the surface of the cathode which might not vibrate or might differently vibrate, and that the current carrying capacity (ampacity) of an initially minimal contact between the dendrite and the cathode will be limited to an uncritical level. Accordingly, it is advantageous to dimension and/or position the ultrasonic transducers in such away that even in front of the surface of the cathode the longitudinal ultrasonic waves, where applicable also shock waves, run in the electrolyte transversely to the longitudinal direction of any dendrites in order to be able to have a maximum effect on them. For example, an ultrasonic transducer may be arranged on either side of the separator at or in the outer wall of the cell of the accumulator.

Lithium dendrites approaching the cathode reduce the electrical impedance of a cell. The impedance can be measured e.g. by the method of electrochemical impedance spectroscopy (“EIS”). Examples of the measuring method, which also relate to lithium-ion accumulators, are disclosed in the publications DE 10 2009 000 336 A1, DE 10 2009 000 337 A1 and DE 10 2013 214 821 A1, to which reference is made for the details of the measuring method. The EIS includes the possibility of carrying out the measurement not only for an accumulator as a whole, but also for individual cells of an accumulator. For very low frequencies, the impedance of lithium-ion cells often shows an almost purely capacitive behavior. To take advantage of this, one measures the impedance advantageously at frequencies no higher than 10 Hz, preferably no higher than 1 Hz.

The impedance measurement opens up the possibility of detecting an impeding short circuit caused by the growth of lithium dendrites before it occurs, because, whereas the impedance of a cell increases as a cell ages, a decrease in impedance is to be expected if dendrites approach the cathode of the cell. A decrease in impedance can be determined by differentiating the measured impedance curve. How clearly the decrease in impedance can be determined in a specific cell design can be clarified by pretests. Since the impedance depends on the temperature and on the frequency with which it is measured, it should be measured always at the same temperature and at the same frequency.

The measurement of the impedance can be carried out in vehicles “in situ”, i.e. while driving (see DE 10 2013 214 821 A1), as well as during standstill, while the accumulator is not being charged and not being discharged (see DE 10 2009 000 336 A1). If a decrease in impedance instead of an increase in impedance is observed by measuring the impedance of a cell of the accumulator, this can indicate an impending short circuit. In this case, one can try to eliminate the danger of a short circuit—without at the same time charging the accumulator—by generating in the cell from which the danger emanates, or in all cells of the accumulator, longitudinal ultrasonic waves, in particular shock waves, in order to break the dendrite or dendrites from which the danger emanates. In order to achieve this, the power of the ultrasonic transducer(s) involved is preferably briefly increased once or several times and the impedance is repeatedly measured in between. If by repeated measurements of the impedance no increase in impedance can be detected, it is advisable to replace the accumulator or at least the cell(s) concerned.

Anhydrous electrolytes suitable for lithium-ion accumulators are known to the person skilled in the art. There is often used a lithium-containing salt in an anhydrous organic solvent, for example a 1-molar solution of lithium borate tetrafluoride (LiBF₄) in propylene carbonate or in a cyclic ether such as tetrahydrofuran (THF). A 1-molar solution of zinc chloride (ZnCl₂) in ethyl methyl carbonate (EMC) or in tetrahydrofuran (THF) is also known as an anhydrous electrolyte.

Separators which are suitable for lithium-ion accumulators and which are permeable to lithium ions are also known to the person skilled in the art. Examples are microporous plastics, in particular polyolefins, including polyethylene and polypropylene, as well as glass fiber mats.

The accompanying drawing shows an embodiment of the invention.

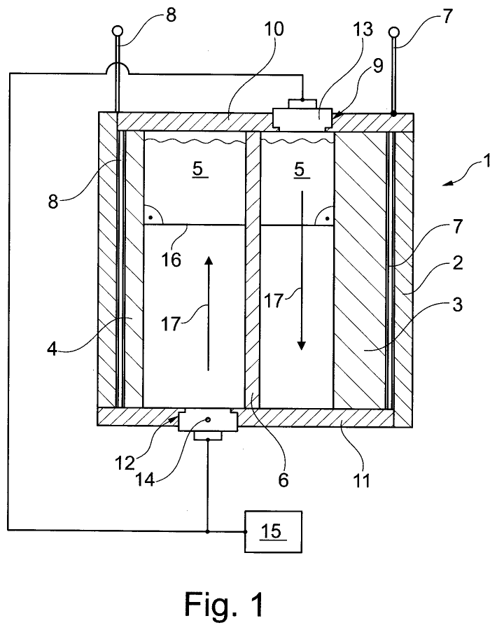

FIG. 1 shows schematically a section through a cell of a lithium-ion accumulator, the section taken perpendicularly through the cathode and the anode.

The cell 1 has a housing 2 made of an electrically insulating material, in particular a plastic. In the housing 2 there is provided an anode 3 and a cathode 4, between which an anhydrous electrolyte 5 and a separator 6 are provided. The anode 3 consists of metallic lithium and is on its back connected to an anode current collector 7, which may consist of copper. The cathode 4 consists of a lithium transition metal oxide, e.g. of LiCo0₂, and is on its back connected to a cathode current collector 8, which may be made of aluminum. The anode current collector 7 and the cathode current collector 8 are led out of the housing 2 and can be connected in a known manner to a direct current source for charging the cell 1 and to a load, for example a direct current motor, for discharging the cell. The separator 6 consists e.g. of a microporous polypropylene. The electrolyte 5 may be a 1-molar solution of LiBF₄ in tetrahydrofuran (THF).

The housing 2 comprises a first recess 9 in a first outer wall 10 of the housing 2 at a location which lies laterally between the anode 3 and the separator 6. In a second outer wall 11 of the housing 2, opposite the first outer wall 10, there is provided a second recess 12 at a location which is laterally offset from the first recess 9 between the cathode 4 and the separator 6, so that the two recesses 9 and 12 lie diagonally opposite each other. The recesses 9 and 12 are open to the outside and to the inside. Into each of the recesses 9 and 12 there is inserted a piezoelectric ultrasonic transducer 13 or 14, respectively, in a liquid-tight manner, e.g. by gluing or welding. To cell 1 there is assigned a frequency generator 15, the frequency of which can be varied under program control. The frequency generator 15 simultaneously feeds both ultrasonic transducers 13 and 14 and receives the power for its operation from the lithium-ion accumulator of which cell 1 is a part.

The frequency generator 15 is so programmed that the frequency of its signal feeding the ultrasonic transmitters 13 and 14 cyclically runs through a frequency range. Preferably, the limits of the frequency range as well as the amplitude of the signal feeding the ultrasonic transducers 13 and 14 can be set at the frequency generator 15.

A straight line 16 in the drawing represents a normal 16 on the front side of the cathode 4 and of the opposite anode 3, i.e. it runs orthogonally to the front side of the cathode 4 and of the anode 3. The direction of the longitudinal ultrasonic waves is symbolically represented by arrows 17.

### List of Reference Numbers

1 cell
2 housing
3 anode
4 cathode
electrolyte
6 separator
7 anode current collector
8 cathode current collector
9 first recess
first wall
11 second wall
12 second recess
13 ultrasonic transducer
14 ultrasonic transducer
frequency generator
16 normal
17 arrows

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. A method for influencing the growth of lithium dendrites in a lithium ion accumulator cell having a cathode and disposed opposite to it an anode comprising at least a lithium containing surface, a liquid electrolyte in an intermediate space between the cathode and the anode, and having a separator permeable to lithium ions, comprising the steps of: introducing longitudinal ultrasonic waves at a variable frequency into the cell during an electrical charging process, such that the longitudinal direction in the electrolyte runs transversely to the normal on the anode and on the cathode, and controlling the frequency of the ultrasonic waves such that it repeatedly passes through a frequency range.

20. The method according to claim 19, further comprising the step of selecting the liquid electrolyte to be an anhydrous electrolyte.

21. The method according to claim 19, further comprising the step of controlling the frequency so that it runs cyclically through the frequency range.

22. The method according to claim 19, further comprising the step of generating the ultrasonic waves during the entire charging process.

23. The method according to claim 19, further comprising the step of generating the ultrasonic waves during a part of the charging process.

24. The method according to claim 19, further comprising the step of occasionally generating ultrasonic shockwaves.

25. The method according to claim 24, further comprising the step of generating the ultrasonic shockwaves at the end of the charging process.

26. The method according to claim 19 applied to an accumulator comprising a plurality of cells, comprising the step of generating the ultrasonic waves at different times for the individual cells.

27. The method according to claim 19 applied to vehicles having an electric motor drive unit being powered by the accumulator, further comprising the steps of generating the ultrasonic waves during each charging process which takes place at a stationary charging station.

28. The method according to claim 19 applied to vehicles having both an electric motor fed by the accumulator and an internal combustion engine as drive units, further comprising the step of generating the ultrasonic waves during driving.

29. The method according to claim 28, further comprising the step of determining that the state of charge of the accumulator has fallen below a predetermined threshold value and then starting the internal combustion engine.

30. The method according to claim 19 applied to an accumulator electrically connected to a frequency generator, further comprising the step of setting the frequency range, and causing the frequency generator to feed at least one ultrasonic transducer which generates and emits the longitudinal ultrasonic waves in the set frequency range.

31. The method according to claim 19, further comprising the step of selecting the frequency range for the generated ultrasonic waves such that at least one resonance occurs in the cell.

32. The method according to claim 31, further comprising the step of selecting the frequency range such that the resonances occur particularly in the electrolyte.

33. The method according to claim 31 applied to an accumulator design, further comprising the step of experimentally determining in advance which frequency range of the ultrasonic waves will create the at least one resonance, and setting thereafter the frequency range to be passed through such that during the charging process at least one of the experimentally determined resonances will occur.

34. The method according to claim 33, further comprising the step of setting the frequency range such that a plurality of the experimentally determined resonances will occur during the charging process.

35. The method according to claim 31, further comprising the step of preferentially selecting and utilizing low resonance frequencies for repetition.

36. The method according to claim 19, further comprising the step of varying the power for generating the ultrasonic waves during the charging process.

37. The method according to claim 36, further comprising the step of increasing the power for generating the ultrasonic waves during the charging process.

38. The method according to claim 19, further comprising the step of generating the ultrasonic waves using at least one ultrasonic transducer located at an outer wall of the cell delimiting the interspace between the cathode and the anode, said location being placed between the cathode and the anode of the cell.

39. The method according to claim 38, wherein said location is located on the outside of the outer wall of the cell.

40. The method according to claim 38, wherein said location is located on the inside of the outer wall of the cell.

41. The method according to claim 38, wherein said location is disposed in a recess provided in the outer wall of the cell.

42. The method according to claim 19, further comprising step of measuring at least once during said charging process the impedance of at least one of the cells of the accumulator, and interrupting the charging process when the measured impedance falls below a selected threshold value.

43. The method according to claim 42, further comprising the step of continuing a generation of ultrasonic waves when the charging process is interrupted.

44. The method according to claim 43, further comprising the step of continuing the generation of ultrasonic waves until the impedance recrosses the selected threshold.

45. The method according to claim 43, further comprising the step of generating ultrasonic waves until a selected time interval has elapsed.

46. The method according to claim 42, further comprising the step of measuring the impedance at a given temperature using the method of electrical impedance spectroscopy (EIS).

47. The method according to claim 42, further comprising the step of measuring the impedance at a frequency which is not higher than 10 Hz.

48. The method according to claim 42, further comprising the step of measuring the impedance at a frequency which is not higher than 1 Hz.

49. The method according to claim 42, further comprising the step of measuring during at least a part of said charging process the chronological course of the impedance at a specified temperature using EIS, and interrupting the charging process when the measured impedance changes its sign from increasing to decreasing.

50. The method according to claim 49, further comprising the step of continuing to generation of ultrasonic waves while the charging process is interrupted.

51. The method according to claim 50, further comprising the step of keeping the charging process interrupted until the impedance increases again.

52. The method according to claim 50, further comprising the step of keeping the charging process interrupted until a specified time interval has elapsed.

53. The method according to claim 52, further comprising the step of at least partly discharging the accumulator after the selected time interval has elapsed.

54. The method according to claim 52, further comprising the step of identifying and replacing the cell of the accumulator which has caused the interruption of the charging process.

55. The method according to claim 24, further comprising the step of generating the ultrasonic shock waves after completion of said charging process.

56. A lithium-ion accumulator having at least one cell having a cathode and disposed opposite to it an anode comprising at least a lithium containing surface, a liquid electrolyte in an intermediate space between the cathode and the anode, a separator provided between the cathode and the anode, the separator being permeable to lithium ions, and at least one ultrasonic transducer for generating longitudinal ultrasonic waves, which is associated to the at least one cell and is arranged and oriented, such that the generated longitudinal ultrasonic waves are transmitted into that at least one cell such that the longitudinal direction of the ultrasonic waves in the electrolyte is transverse to the normal on the anode and the cathode, the accumulator being provided with at least one frequency generator for providing ultrasonic frequencies
